(19) United States
(12) Patent Application Publication
(10) Pub. No.: US 2007/0262427 A1
(43) Pub. Date: Nov. 15, 2007

(54) SEMICONDUCTOR DEVICE

(75) Inventor: Masateru KOIDE, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/781,330

(22) Filed: Jul. 23, 2007

Related U.S. Application Data
(63) Continuation of application No. PCT/JP05/00922, filed on Jan. 25, 2005.

(51) Int. Cl. H01L 23/495

(52) U.S. Cl. 257/675

(57) ABSTRACT

A semiconductor device includes a semiconductor element; a board where the semiconductor element is mounted; a heat radiation member thermally connected to the semiconductor element and fixed to the board; and a plurality of outside connection terminals provided on a surface opposite to a surface where the heat radiation member is provided of the board; wherein a fixing position where the heat radiation member is fixed to the board is substantially positioned on an inscribing circle; and the center of the inscribing circle is a center position of the board and the inscribing circle inscribes the heat radiation member.

### CROSS-REFERENCE TO RELATED APPLICATION

This application is a U.S. continuation application filed under 35 USC 111(a) claiming benefit under 35 USC 120 and 365(c) of PCT application JP2005/000922, filed Jan. 25, 2005. The foregoing application is hereby incorporated herein by reference.

### BACKGROUND OF THE INVENTION

1. Field of the Invention

The present invention generally relates to semiconductor devices. More particularly, the present invention relates to a semiconductor device having a heat radiation member.

2. Description of the Related Art

Recently, accompanying high densities of semiconductor elements, amounts of heat generated from the semiconductor elements have increased. Because of this, a semiconductor device, having a structure where a heat radiation member (a heat sink or the like) thermally connected to a semiconductor element is provided so that heat generated by the semiconductor element is radiated out, has been suggested. See, for example, Japanese Laid-Open Patent Application Publication No. 9-153576.

On the other hand, a BGA (Ball Grid Array) has been known as a package structure of a semiconductor device achieving high density. The BGA type semiconductor device can be formed with a large number of pins and with improved manufacturing efficiency. In the BGA type semiconductor device, the semiconductor element is mounted on a surface of the board and solder bumps are provided on a surface of the board opposite from the surface where the semiconductor element is mounted. The solder bumps are provided in a matrix or along the periphery of the board. In addition, the semiconductor element mounted on the surface of the board is generally sealed by resin.

Furthermore, by providing a heat radiation member on the BGA type semiconductor device, it is possible to achieve both high density and high radiation efficiency. FIG. 1 is a cross-sectional view of a related art semiconductor device of this type.

A semiconductor device 1A shown in FIG. 1 includes a semiconductor element 2, a board 3, a heat spreader 4A, solder balls 5, and others. The board 3 is, for example, a ceramic board. The semiconductor element 2 is flip chip connected on a element mounting surface 3A of the board 3. Under-fill resin 6 is provided between the semiconductor element 2 and the board 3.

The heat spreader 4A is made of a material having high heat conductivity. A center part of the heat spreader 4A is thermally connected to the semiconductor element 2. Accordingly, heat generated by the semiconductor element 2 is transferred to the heat spreader 4A and radiated to the outside so that heat radiation from the semiconductor element 2 can be improved.

In addition, a leg part 7A formed in a body with the heat spreader 4A is adhered to the element mounting surface 3A of the board 3 by an adhesive 8. As a result of this, the heat spreader 4A is fixed to the board 3. Furthermore, the solder balls 5 are provided on a terminal providing surface 3B situated at a surface opposite to the surface where the heat spreader 3 is provided of the board 3.

A large number of the solder balls 5 are provided on the substantially entire surface of the terminal providing surface 3B in a matrix. Thus, in the BGA type semiconductor device 1A, since the solder balls 5 are provide on the entire surface of the terminal providing surface 3B of the board 3, it is possible to realize miniaturization of the device and a large number of pins. In the example shown in FIG. 1, a state where the semiconductor device 1A having the above-discussed structure is mounted on a mother board 9 via the solder balls 5.

FIG. 2 is a plan view showing where the heat spreader 4A is removed from the semiconductor device 1A shown in FIG. 1 and shows a state where the adhesive 8 is provided in the vicinity of the external periphery of the board 3.

As shown in FIG. 2, the adhesive 8 is applied in a rectangular shape along the external peripheral edge of the element mounting surface 3A of the board 3. Accordingly, the position where the heat spreader 4A is fixed to the board 3, namely the position of the adhesive 8, is in the vicinity of the external peripheral edge of the element mounting surface 3A of the board 3 and the configuration of the position where the heat spreader 4A is fixed to the board 3 is substantially rectangular.

However, in this structure where the hat spreader 4A is fixed in the vicinity of the external peripheral edge of the element mounting surface 3A of the board 3, if an external force is applied to the mother board 9 or the heat spreader 4A, high stress is generated in solder balls 5 provided at corner parts A (an area indicated by dash lines in FIG. 2) among the solder balls 5 provided on the substantially entire surface of the terminal providing surface 3B in a matrix. As a result of this, the solder balls 5 provided at the corner parts A may be destroyed.

On the other hand, a semiconductor device 1B shown in FIG. 3 is known as a semiconductor device solving the above-discussed problems.

Here, FIG. 3 is a cross-sectional view of another related art semiconductor device 1B and shows a state where the adhesive 8 is provided in the vicinity of the center of the board 3. In FIG. 3, parts that are the same as the parts shown in FIG. 1 are given the same reference numerals, and explanation thereof is omitted. FIG. 4 is a plan view showing a state where a heat spreader 4B is removed from the semiconductor device 1B shown in FIG. 3 and shows the state where the adhesive 8 is provided in the vicinity of the center of the board 3.

In this semiconductor device 1B, a leg part 7B formed with the heat spreader 4B is formed inside the position of the leg part 7A shown in FIG. 1. The leg part 7B is fixed to the element mounting surface 3A of the board 3 by the adhesive 8 so that the heat spreader 4B is fixed to the board 3.

In this structure, if an external force is applied to the mother board 9 or the heat spreader 4B, stresses applied to the solder balls 5 provided at corner parts A (an area indicated by dash lines in FIG. 4) are reduced and thereby it is possible to prevent the solder balls 5 provided at the corner parts A from being destroyed.

However, an external peripheral part of the heat spreader 4B extends outside from a position where the leg part 7B and the board 3 are fixed. Because of this, if an external force is applied to the corner part 4 of the heat spreader 4B, a bending moment is generated where the fixing point is a fulcrum and the corner part A is a force point.

Therefore, for example, in a case where an external force is applied at a right end part of the heat spreader 4B in FIG. 3, a force indicated by an arrow X is generated at a left end part of the heat spreader 4B. If the force indicated by the arrow X is large, part of the heat spreader 4B may be separated from the board 3.

In the meantime, recently as the semiconductor elements 2 have been fabricated miniaturized and with high density, it is necessary to improve resistance against outside noise. In addition, it is necessary to prevent an electromagnetic field generated by the semiconductor element 2 from adversely affecting an external device due to high processing speed of the semiconductor device 2.

In order to take countermeasure against such noise in the related art semiconductor devices 1A and 1B, shield members are provided separately from the heat spreaders 4A and 4B. However, in this structure, if the number of parts of the semiconductor devices 1A and 1B are increased, it is not possible to miniaturize the device. Furthermore, in the structure where both the heat spreaders 4A and 4B and the shield members are provided in the semiconductor devices 1A and 1B, the heat spreaders 4A and 4B and the shield members interfere with each other. Accordingly, it is not possible to make the heat spreaders 4A and 4B and the shield members have highly efficient configurations and structures.

### SUMMARY OF THE INVENTION

Accordingly, embodiments of the present invention may provide a novel and useful semiconductor device in which one or more of the problems described above are eliminated.

More specifically, the embodiments of the present invention can provide a semiconductor device having high reliability where an outside connection terminal and a heat radiation member are not damaged even if an external force is applied.

In addition, the embodiments of the present invention can provide a semiconductor device whereby influence of outside noise can be prevented by a small number of parts.

The embodiments of the present invention can also provide a semiconductor device, including a semiconductor element; a board where the semiconductor element is mounted; a heat radiation member thermally connected to the semiconductor element and fixed to the board; and a plurality of outside connection terminals provided on a surface opposite to a surface where the heat radiation member is provided of the board; wherein a fixing position where the heat radiation member is fixed to the board is substantially positioned on an inscribing circle; and the center of the inscribing circle is a center position of the board and the inscribing circle inscribes the heat radiation member.

The embodiments of the present invention can also provide a ball grid array type semiconductor device, including a semiconductor element; a board where the semiconductor element is mounted; a heat radiation member thermally connected to the semiconductor element and fixed to the board; and a plurality of outside connection terminals provided on a surface opposite to a surface where the heat radiation member is provided of the board; wherein the heat radiation member is made of a conductive material and is connected to a ground electrode of the board.

The embodiments of the present invention can also provide a ball grid array type semiconductor device, including a semiconductor element; a board where the semiconductor element is mounted; a heat radiation member thermally connected to the semiconductor element and fixed to the board; and a plurality of outside connection terminals provided on a surface opposite to a surface where the heat radiation member is provided of the board; wherein the heat radiation member is formed of a conductive material and connected to a ground electrode of the board; a fixing position where the heat radiation member is fixed to the board is substantially positioned on an inscribing circle; and the center of the inscribing circle is a center position of the board and the inscribing circle inscribes the heat radiation member.

According to the embodiments of the present invention, it is possible to prevent an excessive stress from being applied to an outside connection terminal provided on a corner part of a board and also possible to prevent the outside connection terminal provided on the corner part of the board from being damaged. Furthermore, it is possible to prevent outside noise from reaching a semiconductor element via the heat radiation member and prevent noise from leaking from the semiconductor element to the outside.

Other objects, features, and advantages of the present invention will become more apparent from the following detailed description when read in conjunction with the accompanying drawings.

### BRIEF DESCRIPTION OF THE DRAWINGS

FIG. 1 is a cross-sectional view of a related art semiconductor device;

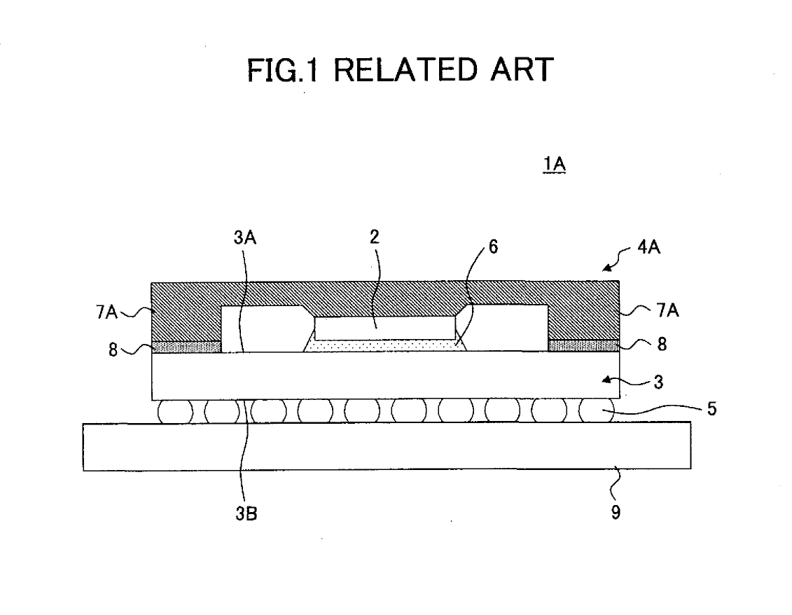

FIG. 2 is a plan view showing a state where a heat spreader is removed from the semiconductor device shown in FIG. 1 and shows a state where an adhesive is provided in the vicinity of an external periphery of a board;

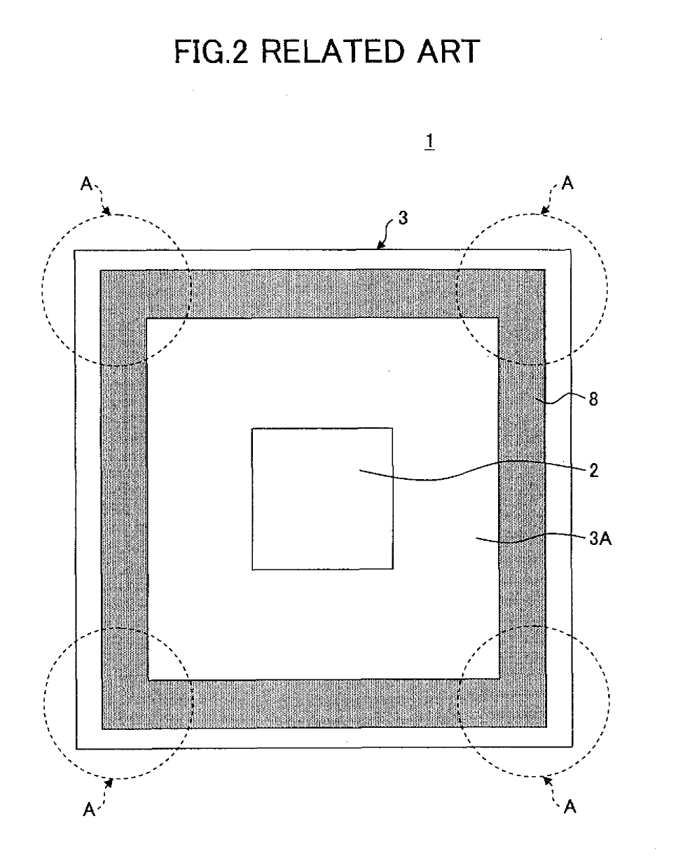

FIG. 3 is a cross-sectional view of another related art semiconductor device and shows a state where an adhesive is provided in the vicinity of the center of the board;

FIG. 4 is a plan view showing a state where a heat spreader is removed from the semiconductor device shown in FIG. 3 and shows the state where an adhesive is provided in the vicinity of the center of the board;

FIG. 5 is a cross-sectional view of a semiconductor device of a first embodiment of the present invention;

FIG. 6 is a plan view showing a state where a heat spreader is removed from the semiconductor device shown in FIG. 5 and shows a state where an adhesive is provided in the vicinity of an external periphery of a board;

FIG. 7 is a cross-sectional view of a semiconductor device of a second embodiment of the present invention;

FIG. 8 is a plan view showing a state where a heat spreader is removed from the semiconductor device shown in FIG. 7 and shows a state where an adhesive is provided in the vicinity of an external periphery of a board;

FIG. 9 is a cross-sectional view of a semiconductor device of a third embodiment of the present invention; and

FIG. 10 is a plan view of the semiconductor device of the third embodiment of the present invention.

### DETAILED DESCRIPTION OF THE PREFERRED EMBODIMENT

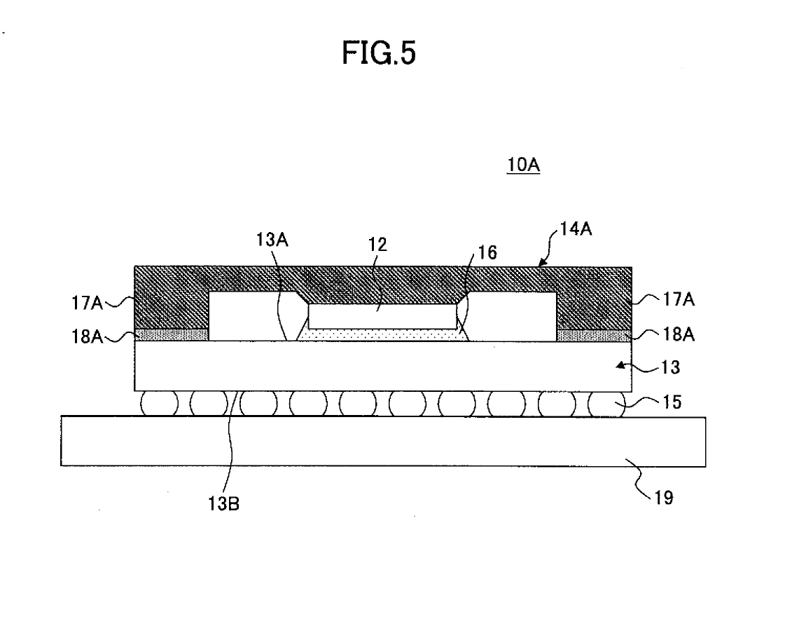

A description will now be given, with reference to FIG. 5 through FIG. 10, of embodiments of the present invention.

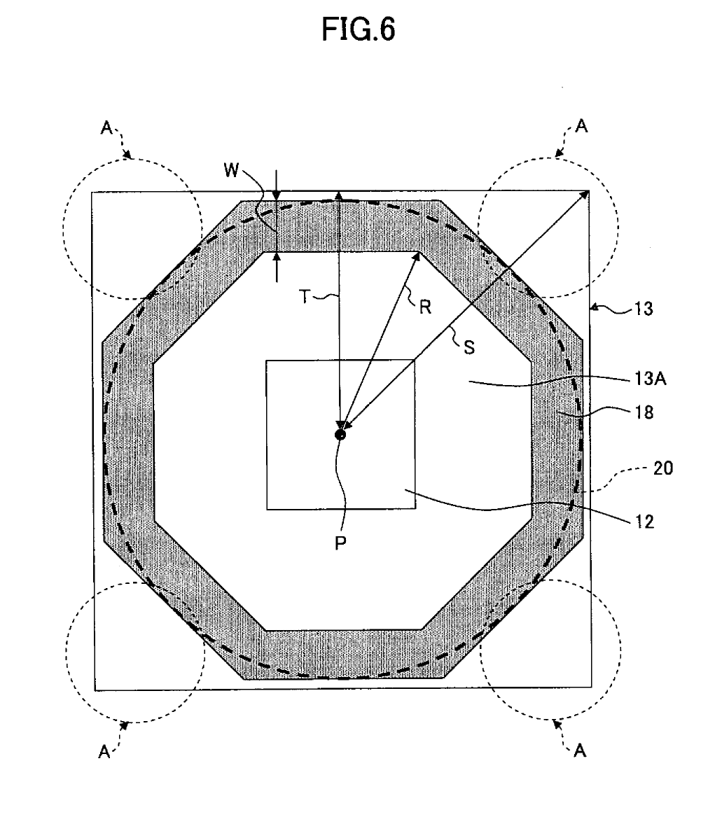

FIG. 5 is a cross-sectional view of a semiconductor device 10A of a first embodiment of the present invention. FIG. 6 is a plan view showing a state where a heat spreader 14A is removed from the semiconductor device 10A shown in FIG. 5 and shows a state where an adhesive 18A is provided in the vicinity of an external periphery of a board 13.

The semiconductor device 10A shown in FIG. 5 and FIG. 6 is a BGA (Ball Grid Array) type semiconductor device. The semiconductor device 10A includes a semiconductor element 12, a board 13, a heat spreader (heat radiation member) 14A, solder balls (outside connection terminals) 15 and others. The board 13 is a ceramic board and wirings are formed on surfaces of and inside the board 13. In the explanation below, a surface of the board 13 where the semiconductor element 13 is mounted is called an element mounting surface 13A and a surface of the board 13 where the solder balls 15 are provided is called a terminal providing surface 13B. It is not always necessary for the board 13 to have a multi-layer structure and there is no need to limit the board 13 to a resin board.

The semiconductor element 12 is a high density element and has a large number of electrodes. Bumps are formed on the electrodes so that the semiconductor element 12 is flip-chip bonded to the board 13. In addition, Under-fill resin 6 is provided between the board 13 and the semiconductor element 12 flip-chip bonded to the board 13 so as to protect the bumps.

The heat spreader 14A is made of metal member or the like having high heat conductivity such as copper (Cu), aluminum (Al) or Aluminum Silicon Carbide (AlSiC). A center part of the heat spreader 14A is thermally connected to the semiconductor element 12. A material having a high thermal conductivity may be provided between the semiconductor element 12 and the heat spreader 14A.

Thus, since the semiconductor element 12 is thermally connected to the heat spreader 14A, heat generated by the semiconductor element 12 is radiated outside via the heat spreader 14A. Hence, it is possible to efficiently radiate the heat generated by the semiconductor element 12 outside the semiconductor device 10A.

In addition, a leg part 17A is formed in a body with the heat spreader 14A. The leg part 17A is adhered to the element mounting surface 13A by using an adhesive 18A. Because of this, the heat spreader 14A is fixed to the board 13. The position of this leg part 17A corresponds to a position where the adhesive 18A discussed below is provided.

In the first embodiment of the present invention, the leg part 17A is formed in a ring shaped manner so as to surround the semiconductor element 12. Therefore, by adhering and fixing the leg part 17A to the board 13, the semiconductor element 12 is sealed by the heat spreader 14A. In other words, the heat spreader 14A works as a lid configured to protect the semiconductor element 12. Thus, the head spreader 14A works as not only the heat radiation member but also the lid. Therefore, protection of the semiconductor element 12 can be securely achieved by a small number of parts.

A large number of the solder balls 15 are provided on a substantially entire surface of the terminal providing surface 13B in a matrix. Thus, since the semiconductor device 10A has the solder balls 15 as the outside connection terminal provided on the substantially entire surface of the terminal providing surface 13B, it is possible to realize miniaturization of the device and a large number of pins. In the example shown in FIG. 5, the semiconductor device 10A having the above-discussed structure is mounted on a mother board 19.

Here, a fixing position where the heat spreader 14A is fixed to the board 13 is discussed. In the first embodiment of the present invention, the fixing position where the heat spreader 14A is fixed to the board 13, namely a providing position of the adhesive 18A, is substantially positioned on an inscribing circle 20. The center of the inscribing circle 20 is a center position indicated by “P” in FIG. 6 of the board 13. The inscribing circle 20 inscribes the heat spreader 14A.

The inscribing circle 20 in this embodiment is not limited to a circle coming in contact with an external peripheral edge of the heat spreader 14A but has a designated area. More specifically, as shown in FIG. 6, the inscribing circle 20 satisfies a condition of “(S/2)≦R≦T”, wherein the radius of the inscribing circle 20 is “R”, the distance from the center position P of the board 13 to the corner of the board 13 is “S”, and the distance from the center position P of the board 13 to a shortest external peripheral edge of the board 13 is “T”.

In addition, that the fixing position (the providing position of the adhesive 18A) is substantially positioned on the inscribing circle 20 does not mean that the center of the fixing position is not always positioned on the center of the inscribing circle 20 when the heat spreader 14A is fixed to the board 13. In other words, even if the center of the fixing position is slightly shifted from the inscribing circle 20, as long as it is in an area where the heat spreader 14A is stably fixed to the board 13, in this embodiment, it is considered that the fixing position is positioned on the inscribing circle 20. Furthermore, more specifically, in a case where at least a part of the fixing position comes in contact with the inscribing circle 20, it is considered that the fixing position is positioned on the inscribing circle 20.

In addition, an area where the inscribing circle 20 and the adhesive 18A come in contact with each other changes depending on the width measurement of the adhesive 18A indicated by an arrow W in FIG. 6. Therefore, in a case where the width measurement W is excessive, a structure where the corner part A is fixed by the adhesive 18A is included. However, in the first embodiment of the present invention, the width measurement W of the adhesive 18A is a substantially minimum value so that the heat spreader 14A can be securely fixed to the board 13.

Under this structure, the corner of the board 13 is separated from the fixing position (the adhesive 18A). Accordingly, it is possible to prevent an excessive stress from being applied to the solder ball 15 provided at a corner part of the board 13 (an area A including the corner of the board 13 and surrounded by dotted lines in FIG. 6). Because of this, it is possible to prevent the solder ball 15 provided at the corner part A of the board 13 from being damaged when an external force is applied to the mother board 19 or the heat spreader 14A. Therefore, it is possible to improve the reliability of the semiconductor device 10A.

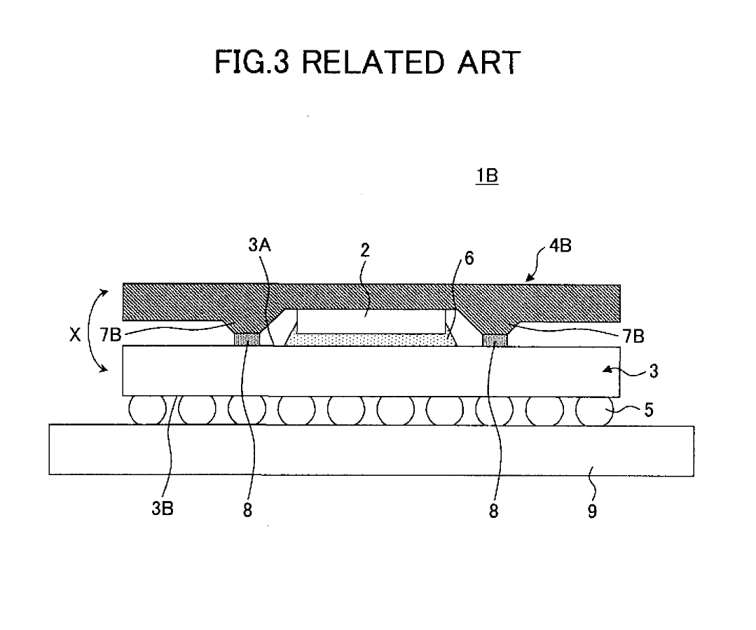

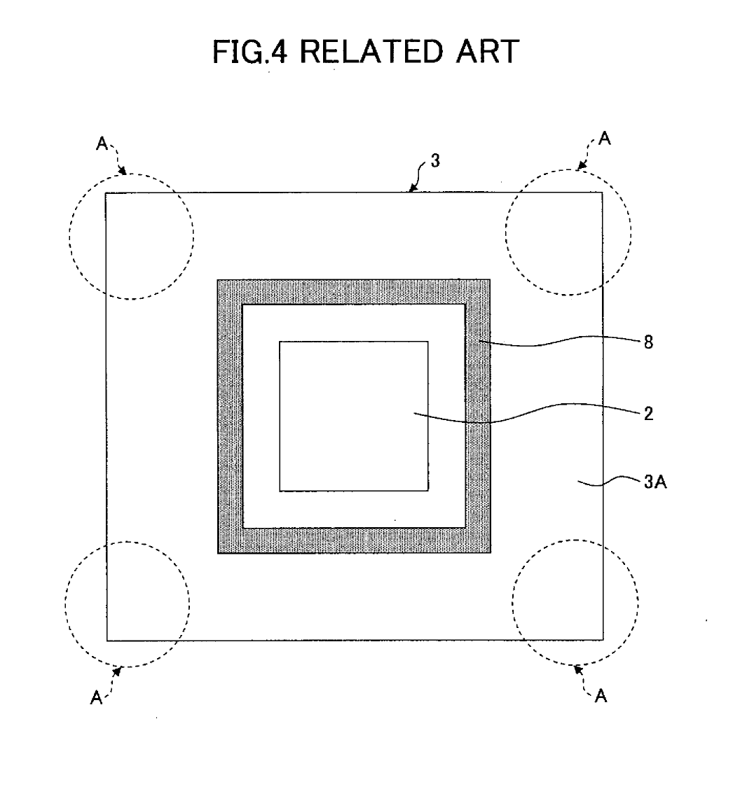

In the structure of this embodiment compared to the structure of the related art semiconductor device 1B shown in FIG. 3 and FIG. 4, the fixing position is relatively separated from the center position P of the board 13. Therefore, it is possible to stably fix the heat spreader 14A to the board 13. Accordingly, it is possible to prevent the heat spreader 14A from being separated from the board 13 even if the external force is applied. Because of this, it is possible to improve the reliability of the semiconductor device 10A.

In the meantime, it is preferable that a plan view configuration of the fixing position, namely a configuration of the arranging position of the adhesive 8, be circular-shaped from the view point of balance. However, the plan view configuration of the fixing position is not limited to a circular-shaped configuration.

It is preferable that the configuration of the plan view of the fixing position be a polygonal shape equal to or greater than a hexagon so that the heat spreader 14A is fixed to the board 13 with high reliability. In this embodiment, the configuration of the plan view of the adhesive 18A is octagonal-shaped.

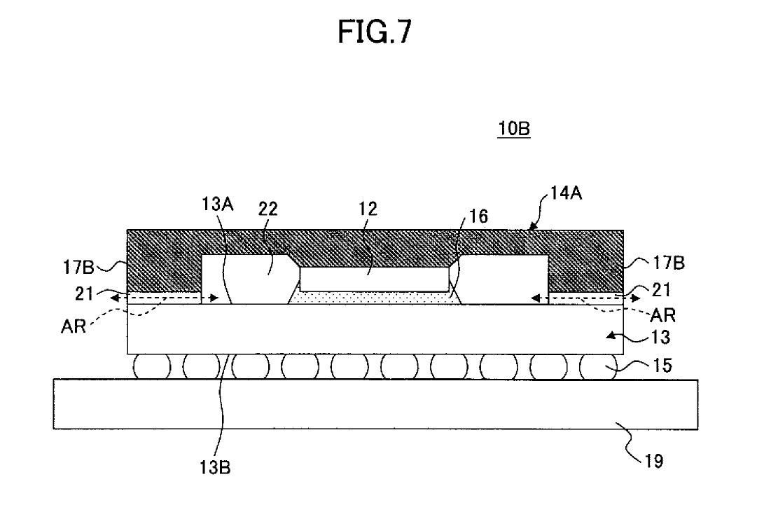

Next, a second embodiment and a third embodiment of the present invention are discussed with reference to FIG. 7 through FIG. 10. In FIG. 7 through FIG. 10, parts that are the same as the parts shown in FIG. 5 and FIG. 6 are given the same reference numerals, and explanation thereof is omitted.

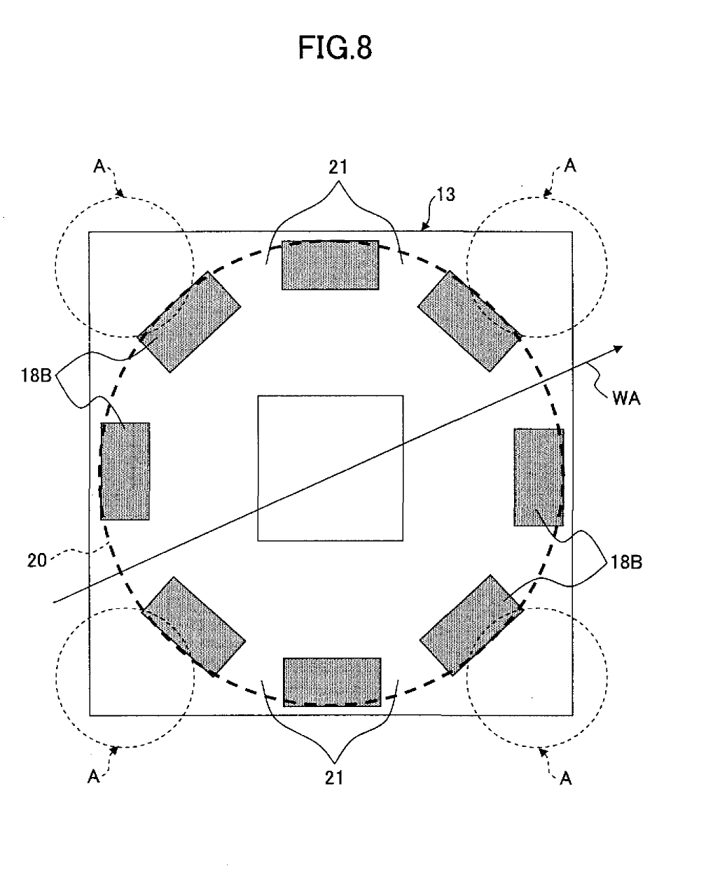

FIG. 7 is a cross-sectional view of a semiconductor device 10B of the second embodiment of the present invention. FIG. 8 is a plan view showing a state where a heat spreader 14A is removed from the semiconductor device 10B shown in FIG. 7 and shows a state where adhesives 18B are provided in the vicinity of the external periphery of the board 13.

In the semiconductor device 10A of the above-discussed first embodiment of the present invention, the leg part 17A is formed in a ring shape so that the semiconductor element 2 is completely sealed by the heat spreader 14A. On the other hand, in the semiconductor device 10B of this embodiment, the fixing position where the heat spreader 14A is fixed to the board 13 is divided into plural positions on the above-discussed inscribing circle 20.

More specifically, a leg part 17B formed in a body with the heat spreader 14A is divided into plural parts (eight parts in this embodiment). The divided leg part 17B is fixed to the element mounting surface 13A by the adhesive 18B. Because of this, space forming part 21 are formed between neighboring leg parts 17B. Via the space forming part 21, an internal space of the heat spreader 14A (hereinafter a cavity forming part 22) and an outside of the device are connected to each other.

Under this structure, for example, even if a heating process is applied at the time when the semiconductor device 10B is mounted on the mother board 19 or the like so that air in the cavity forming part 22 is heated and expanded, the expanded air is discharged outside via the space forming parts 21. Air flowing through the space forming part 21 is indicated by dashed arrows AR in FIG. 7. Because of this, it is possible to prevent the heat spreader 14A from being separated from the board 13 due to expansion of air in the cavity forming part 22 at the heating time so that reliability of the semiconductor device 10B can be improved.

Furthermore, in the manufacturing process of the semiconductor device 10B, after the solder balls 15 are soldered and fixed on the board 13, a flux washing process is applied. Such a washing process is performed several times during the manufacturing process of the semiconductor device 10B and washing is accomplished mainly by the flow of the washing liquid.

In the related art semiconductor devices 1A and 1B, the heat spreaders 4A and 4B are mounted on the board 3 so as to seal the semiconductor element 12. Therefore, if washing liquid enters the cavity forming part, it is not possible to discharge the washing liquid from the cavity forming part easily. Thus, if a heating process is applied in a state where the washing liquid remains in the cavity forming part, the heat spreaders 4A and 4B may be separated from the board 3 due to volume expansion based on gasification of the washing liquid.

On the other hand, in the semiconductor device 10B of this embodiment, the space forming parts 21 are formed between neighboring leg parts 17B. Therefore, even if the semiconductor device 10B is washed, the washing liquid is smoothly discharged via the air space forming parts 21. Hence, the washing liquid does not remain in the cavity forming part 22. The flow of the washing liquid flowing through the space forming part 21 is indicated by solid lines WA in FIG. 8. Accordingly, even if the heating process is implemented after the washing process is performed, it is possible to prevent the heat spreader 14A from being separated from the board 13 so that reliability of the semiconductor device 10B can be improved.

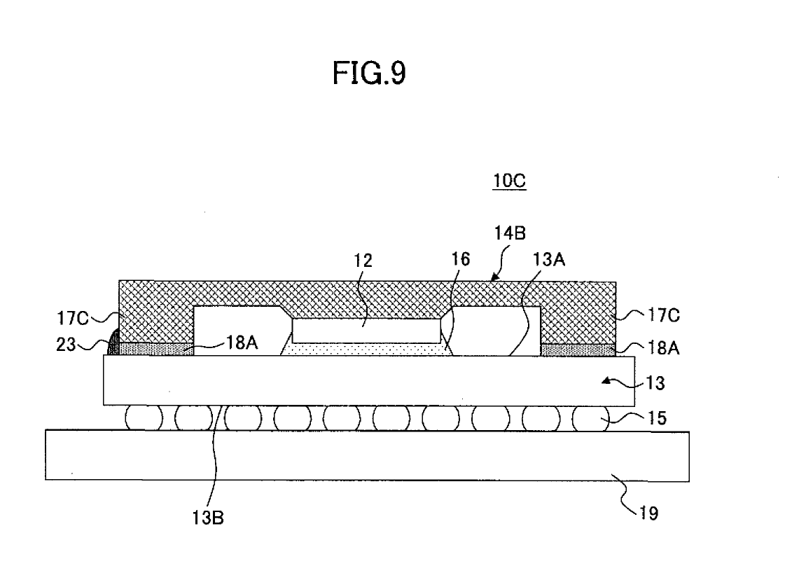

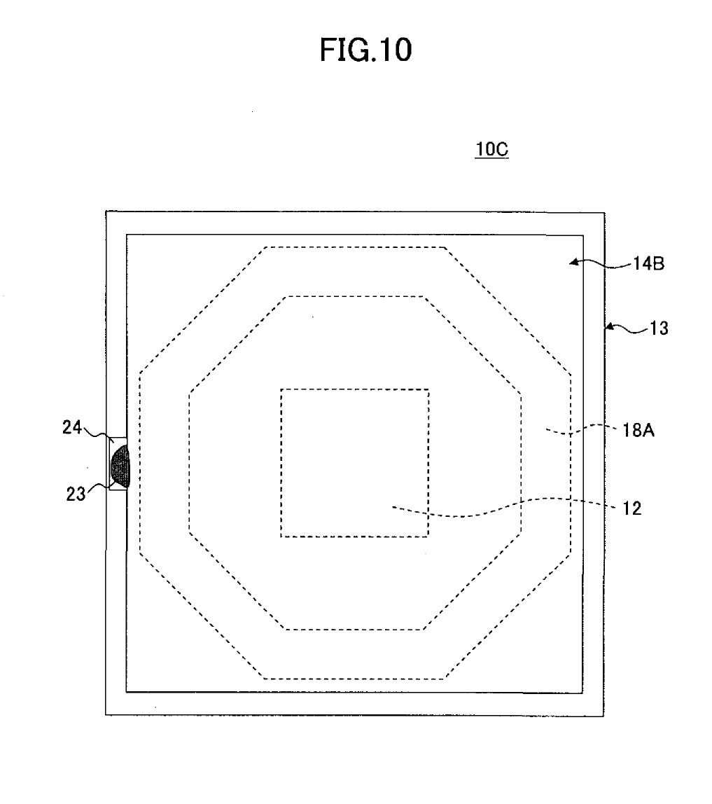

FIG. 9 is a cross-sectional view of a semiconductor device 10C of the third embodiment of the present invention. FIG. 10 is a plan view of the semiconductor device 10C of the third embodiment of the present invention.

In the semiconductor device 10A and 10B of the first embodiment and the second embodiment of the present invention, the heat spreader 14A is used as only the heat radiation member and electromagnetic actions of the semiconductor device 10A and 10B are not considered. On the other hand, in the semiconductor device 10C of this embodiment, the heat spreader 14B is formed of a conductive material and connected to a ground electrode 24 formed at the board 13.

The heat spreader 14B has the same configuration as the heat spreader 14A used for the semiconductor device 10A and 10B of the first embodiment and the second embodiment of the present invention. The heat spreader 14B is made of a conductive material effective for electromagnetic noise shielding such as copper (Cu) or aluminum silicon carbide (AlSiC). On the other hand, at the board 13, the ground electrode 24 is formed in an entirety or a part of a position where the leg part 17C of the heat spreader 14B is fixed to the element mounting surface 13A. In this embodiment, the ground electrode 24 is formed at a part of an area where the leg part 17C is fixed to the element mounting surface 13A.

The heat spreader 14B and the ground electrode 24 are mechanically and electrically connected to each other by using the conductive adhesive 23. Thus, by using the conductive adhesive 23, it is possible to easily and securely connect the heat spreader 14B and the ground electrode 24. In addition, by electrically connecting the heat spreader 14B formed of the conductive material to the ground electrode 24 of the board 13, the heat spreader 14B works as not only the heat radiation member but also the shield member. Accordingly, while the number of parts is decreased, it is possible to prevent outside noise from entering via the heat spreader 14B to the semiconductor element 12 and prevent noise from leaking from the semiconductor element 12 to the outside. Thus, according to the above-discussed embodiment, it is possible to realize the semiconductor device 10C having good noise resistance properties and high reliability at low cost.

According to the above-discussed embodiments of the present invention, it is possible to provide a semiconductor device, including a semiconductor element; a board where the semiconductor element is mounted; a heat radiation member thermally connected to the semiconductor element and fixed to the board; and a plurality of outside connection terminals provided on a surface opposite to a surface where the heat radiation member is provided of the board; wherein a fixing position where the heat radiation member is fixed to the board is substantially positioned on an inscribing circle; and the center of the inscribing circle is a center position of the board and the inscribing circle inscribes the heat radiation member.

According to the above-mentioned structure, the fixing position where the heat radiation member is fixed to the board is substantially positioned on the inscribing circle. The center of the inscribing circle is a center position of the board and the inscribing circle inscribes the board. Therefore, since the corner of the board and the fixing position are separated from each other, it is possible to prevent an excessive stress from being applied to the outside connection terminal provided on the corner part of the board. Because of this, it is possible to prevent the outside connection terminal provided on the corner part of the board from being damaged when the external force is applied.

In addition, the fixing position is substantially positioned on the inscribing circle which inscribes the board. Therefore, the fixing position is relatively removed from the center position of the board. Because of this, it is possible to stably fix the heat radiation member to the board and it is possible to prevent the heat radiation member from being separated from the board even if an external force is applied. Here, “substantially positioned” means that a structure where the fixing position is shifted from the inscribing circle in an area where the stability can be realized also belongs to the present invention.

A configuration of a plan view of the fixing position may be a polygonal shape equal to or greater than hexagon. A configuration of a plan view of the fixing position may be a circular shape.

The inscribing circle may satisfy a condition of “(S/2)≦R≦T”, where the radius of the inscribing circle is “R”, the distance from the center position of the board to the corner of the board is “S”, and the distance from the center position of the board to a shortest external peripheral edge of the board is “T”.

According to the above-mentioned structure, the fixing position is separated from the corner and the center position of the board. Therefore, it is possible to prevent the outside connection terminal provided on the corner part of the board from being damaged when the external force is applied and it is possible to prevent the heat radiation member from being separated from the board.

The fixing position where the heat radiation member is fixed to the board may be divided into a plurality of positions on the inscribing circle.

According to the above-mentioned structure, for example, even if a heating process is applied at the time when the semiconductor device is mounted on the mother board or the like so that air in the heat radiation member is heated and expanded, the expanded air is discharged outside via a space between the divided fixing positions. Because of this, it is possible to prevent the heat radiation member from being separated from the board due to expansion of air at the heating time. In addition, in a washing process, since washing liquid flows through the space between the divided arranged fixing position, it is possible to prevent the washing liquid from remaining in the heat radiation member and to improve washing efficiency.

The heat radiation member may work as a lid configured to protect the semiconductor element.

According to the above-mentioned structure, the heat radiation member works as the lid and protects the semiconductor element. Therefore, it is possible to decrease the number of parts.

The heat radiation member may directly comes in contact with the semiconductor element.

According to the above-mentioned structure, it is possible to radiate heat generated by the semiconductor element efficiently.

According to the above-discussed embodiments of the present invention, it is possible to provide a ball grid array type semiconductor device, including: a semiconductor element; a board where the semiconductor element is mounted; a heat radiation member thermally connected to the semiconductor element and fixed to the board; and a plurality of outside connection terminals provided on a surface opposite to a surface where the heat radiation member is provided of the board; wherein the heat radiation member is made of a conductive material and is connected to a ground electrode of the board.

According to the above-mentioned structure, the heat radiation member is made of the conductive material and is connected to the ground electrode of the board. Accordingly, it is possible to prevent outside noise from entering the semiconductor element via the heat radiation member and prevent noise from leaking from the semiconductor element to the outside.

The heat radiation member and the ground electrode may be mechanically and electrically connected to each other by using a conductive adhesive.

According to the above-mentioned structure, it is possible to connect the heat radiation member and the ground electrode to each other easily, electrically, mechanically, and securely.

According to the above-discussed embodiments of the present invention, it is possible to provide a ball grid array type semiconductor device, including a semiconductor element; a board where the semiconductor element is mounted; a heat radiation member thermally connected to the semiconductor element and fixed to the board; and a plurality of outside connection terminals provided on a surface opposite to a surface where the heat radiation member is provided of the board; wherein the heat radiation member is formed of a conductive material and connected to a ground electrode of the board; a fixing position where the heat radiation member is fixed to the board is substantially positioned on an inscribing circle; and the center of the inscribing circle is a center position of the board and the inscribing circle inscribes the heat radiation member.

Thus, according to the semiconductor devices of the embodiments of the present invention, it is possible to prevent outside noise from entering the semiconductor element via the heat radiation member and prevent the noise from leaking from the semiconductor element to the outside. In addition, it is possible to prevent an excessive stress from being applied to the outside connection terminal provided on the corner part of the board and also possible to prevent the outside connection terminal provided on the corner part of the board from being damaged.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

For example, in the above-discussed embodiments, the conductive adhesive 23 is used for connecting the heat spreader 14B and the ground electrode 24 to each other. However, a member for connecting the heat spreader 14B and the ground electrode 24 to each other is not limited to the adhesive. Metal such as solder or other connection material may be used as the member for connecting the heat spreader 14B and the ground electrode 24 to each other.

The heat spreader 14B and the ground electrode 24 can be connected to each other by making the adhesives 18A and 18B instead of the conductive adhesive 23 have conductivity, forming the ground electrode at the board 13, and connecting the adhesives 18A and 18B having conductivities to the ground electrode formed at the board 13.

What is claimed is:

1. A semiconductor device, comprising:
a semiconductor element;
a board where the semiconductor element is mounted;
a heat radiation member thermally connected to the semiconductor element and fixed to the board; and
a plurality of outside connection terminals provided on a surface opposite to a surface where the heat radiation member is provided of the board;
wherein a fixing position where the heat radiation member is fixed to the board is substantially positioned on an inscribing circle; and
the center of the inscribing circle is a center position of the board and the inscribing circle inscribes the heat radiation member.

2. The semiconductor device as claimed in claim 1,
wherein a configuration of a plan view of the fixing position is a polygonal shape equal to or greater than hexagon.

3. The semiconductor device as claimed in claim
wherein a configuration of a plan view of the fixing position is a circular shape.

4. The semiconductor device as claimed in claim 1,
wherein the inscribing circle satisfies a condition of “(S/2)≦R≦T”, where the radius of the inscribing circle is “R”, the distance from the center position of the board to the corner of the board is “S”, and the distance from the center position of the board to a shortest external peripheral edge of the board is “T”.

5. The semiconductor device as claimed in claim
wherein the fixing position where the heat radiation member is fixed to the board is divided into a plurality of positions on the inscribing circle.

6. The semiconductor device as claimed in claim 1,
wherein the heat radiation member works as a lid configured to protect the semiconductor element.

7. The semiconductor device as claimed in claim
wherein the heat radiation member directly comes in contact with the semiconductor element.

8. A ball grid array type semiconductor device, comprising:
a semiconductor element;
a board where the semiconductor element is mounted;
a heat radiation member thermally connected to the semiconductor element and fixed to the board; and
a plurality of outside connection terminals provided on a surface opposite to a surface where the heat radiation member is provided of the board;
wherein the heat radiation member is made of a conductive material and is connected to a ground electrode of the board.

9. The ball grid array type semiconductor device as claimed in claim 8,
wherein the heat radiation member and the ground electrode are mechanically and electrically connected to each other by using a conductive adhesive.

10. A ball grid array type semiconductor device, comprising:
a semiconductor element;
a board where the semiconductor element is mounted;
a heat radiation member thermally connected to the semiconductor element and fixed to the board; and
a plurality of outside connection terminals provided on a surface opposite to a surface where the heat radiation member is provided of the board;
wherein the heat radiation member is formed of a conductive material and connected to a ground electrode of the board;
a fixing position where the heat radiation member is fixed to the board is substantially positioned on an inscribing circle; and
the center of the inscribing circle is a center position of the board and the inscribing circle inscribes the heat radiation member.

11. The ball grid array type semiconductor device as claimed in claim 10,
wherein a configuration of a plan view of the fixing position is a polygonal shape equal to or greater than hexagon.

12. The ball grid array type semiconductor device as claimed in claim 10,
wherein a configuration of a plan view of the fixing position is a circular shape.

13. The ball grid array type semiconductor device as claimed in claim 10,
wherein the inscribing circle satisfies a condition of “(S/2)≦R≦T”, where the radius of the inscribing circle is “R”, the distance from the center position of the board to the corner of the board is “S”, and the distance from the center position of the board to a shortest external peripheral edge of the board is “T”.

14. The ball grid array type semiconductor device as claimed in claim 10,
wherein the fixing position where the heat radiation member is fixed to the board is divided into a plurality of positions on the inscribing circle.

15. The ball grid array type semiconductor device as claimed in claim 10,
wherein the heat radiation member works as a lid configured to protect the semiconductor element.

16. The ball grid array type semiconductor device as claimed in claim 10,
wherein the heat radiation member directly comes in contact with the semiconductor element.

17. The ball grid array type semiconductor device as claimed in claim 10,
wherein the heat radiation member and the ground electrode are mechanically and electrically connected to each other by using a conductive adhesive.
